(19) United States
(12) Patent Application Publication
(10) Pub. No.: US 2009/0269897 A1
(43) Pub. Date: Oct. 29, 2009

(54) METHODS OF FABRICATING DUAL-DEPTH TRENCH ISOLATION REGIONS FOR A MEMORY CELL

(75) Inventors: Brent A. Anderson, Jericho, VT (US); Andres Bryant, Burlington, VT (US); Josephine B. Chang, Mahopac, NY (US); Michael A. Guillorn, Yorktown Heights, NY (US); Ryoji Hasumi, Crompond, NY (US); Edward J. Nowak, Essex Junction, VT (US); Mickey H. Yu, Essex Junction, VT (US)

Correspondence Address: WOOD, HERRON & EVANS, LLP (IBM-BUR), 2700 CAREW TOWER, 441 VINE STREET, CINCINNATI, OH, 45202, US

(73) Assignee: INTERNATIONAL BUSINESS MACHINES CORPORATION, Armonk, NY (US)

(21) Appl. No.: 12/111,266

(22) Filed: Apr. 29, 2008

(51) Int. Cl. H01L 21/8234

(52) U.S. Cl. 438/275; 257/E21.616

(57) ABSTRACT

Methods for fabricating dual-depth trench isolation regions for a memory cell. First and second deep trench isolation regions are formed in the semiconductor layer that laterally bound a device region in a well of a first conductivity type in the semiconductor layer. First and second pluralities of doped regions of a second conductivity type are formed in the device region. A shallow trench isolation region is formed that extends laterally across the device region from the first deep trench isolation region to the second deep trench isolation region. The shallow trench isolation region is disposed in the device region between the first and second pluralities of doped regions. The shallow trench isolation region extends into the semiconductor layer to a depth such that the well is continuous beneath the shallow trench isolation region. A gate stack controls carrier flow between a pair of the first plurality of doped regions.

### CROSS-REFERENCE TO RELATED APPLICATIONS

This application is related to application Ser. No. ______, filed as Attorney Docket No. BUR920080070US2 on Apr. 29, 2008 and entitled “Device Structures Including Dual-Depth Trench Isolation Regions And Design Structures For A Static Random Access Memory,” the disclosure of which is hereby incorporated by reference herein in its entirety.

### FIELD OF THE INVENTION

The invention relates generally to semiconductor device fabrication and, in particular, to methods of fabricating a device structure for a memory cell.

### BACKGROUND OF THE INVENTION

Static random access memories (SRAMs) fabricated using complementary metal-oxide-semiconductor (CMOS) processes have been exploited in various low-power memory devices found in consumer goods and portable office equipment. A full-CMOS SRAM has multiple memory cells each containing an array of low power CMOS field effect transistors. Typically, the arrays of field effect transistors are formed with reliance upon N-wells and P-wells defined in a P-type substrate. Deep trench isolation regions are used for inter-well isolation and shallow trench isolation regions are used for intra-well isolation. Because they are formed within a substrate of a common conductivity type, the P-wells are continuous. In contrast, the continuity of the N-wells is maintained by the shallow trench isolation regions so that a common N-well contact can be established external to each array of field effect transistors. One of the deep trench isolation regions is located at each inter-well boundary between wells of opposite conductivity type. This strategy minimizes the spacing between N-channel field effect transistors (NFETs) and P-channel field effect transistors (PFETs) spacing in the SRAM, which promotes greater packing densities for the memory cells.

The need to integrate more functionality into an integrated circuit has prompted the semiconductor industry to seek approaches to shrink, or scale, the size of individual field effect transistors and other devices commonly integrated into the integrated circuit. As technology scales, the minimum width and length of the semiconductor devices shrink. However, scaling devices to smaller dimensions may cause a multitude of undesirable consequences. In SRAMs as well as other low power CMOS integrated circuits, the threshold voltage of the NFETs and PFETS is extremely sensitivity to the width. The conventional trench isolation scheme results in FETs in a SRAM that are bounded by both deep and shallow trench isolation regions, which effectively defines the device width. As a result, misalignment between deep trench isolation regions and shallow trench isolation regions imparts device width variations, which in turn causes variations in the threshold voltage.

What is needed, therefore, are improved methods for fabricating trench isolation regions for memory cells that overcome these and other deficiencies of conventional trench isolation schemes used in memory cell constructions.

### SUMMARY OF THE INVENTION

In accordance with an embodiment of the invention, a method is provided for fabricating a device structure using a semiconductor layer having a top surface. The method includes forming a well of a first conductivity type in the semiconductor layer and forming first and second deep trench isolation regions in the semiconductor layer that laterally bound a device region in the well. A first plurality of doped regions of a second conductivity type and a second plurality of doped regions of the second conductivity type are formed in the device region. The method further includes forming a shallow trench isolation region that extends laterally across the device region from the first deep trench isolation region to the second deep trench isolation region. The shallow trench isolation region is disposed in the device region between the first plurality of doped regions and the second plurality of doped regions. The shallow trench isolation region extends from the top surface into the semiconductor layer to a depth such that the well is continuous beneath the shallow trench isolation region. A gate stack, which is formed on a top surface of the semiconductor layer, is configured to control carrier flow between one of the first plurality of doped regions and another of the first plurality of doped regions.

### BRIEF DESCRIPTION OF THE DRAWINGS

The accompanying drawings, which are incorporated in and constitute a part of this specification, illustrate embodiments of the invention and, together with a general description of the invention given above and the detailed description of the embodiments given below, serve to explain the principles of the invention.

FIG. 1 is a diagrammatic top plan view of a device structure built on a portion of a semiconductor-on-insulator wafer at an initial fabrication stage according to a processing method in accordance with an embodiment of the invention.

FIGS. 2 and 3 are diagrammatic cross-sectional views taken generally along line 2-2 and line 3-3, respectively, in FIG. 1.

FIG. 4 is a flow diagram of a design process used in semiconductor design, manufacture, and/or test.

### DETAILED DESCRIPTION

Generally, embodiments of the invention relate to dual depth trench isolation for use in integrated circuits. In one embodiment, the dual depth trench isolation is used in conjunction with SRAM memory cells, each of which contains an array of interconnected field effect transistors (FETs). The dual depth trench isolation includes continuous deep trench isolation regions bounding the FET widths. The deep trench isolation regions are continuous in a direction substantially perpendicular to the direction of the FET gates. The dual depth trench isolation further includes shallow trench isolation regions that isolate the diffusions of the PFETs between the deep trench isolation regions and well regions (e.g., N-wells) that are continuous between the deep trench isolation regions and, in addition, are continuous beneath the shallow trench isolation regions.

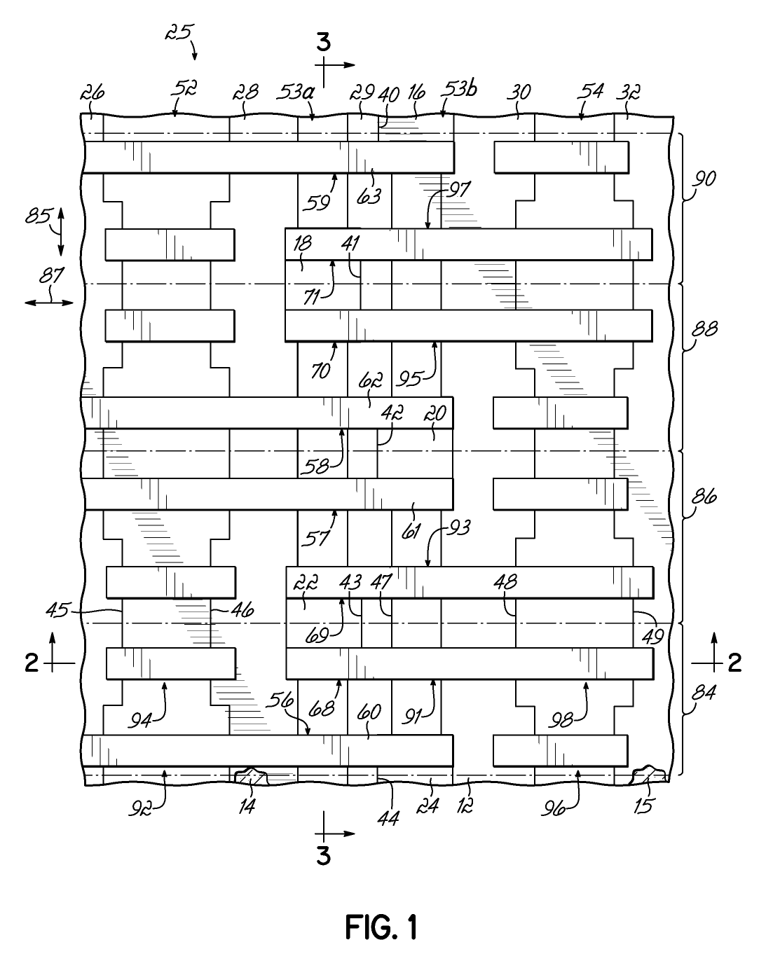

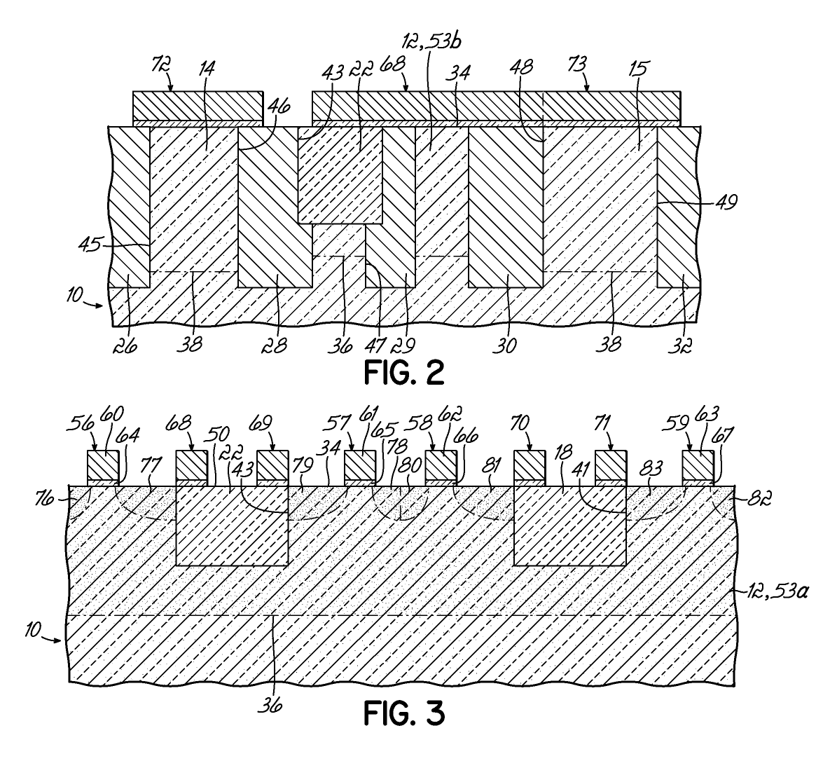

With reference to FIGS. 1-3 and in accordance with an embodiment of the invention, a substrate 10 is provided or obtained that may be any type of conventional monocrystalline semiconductor substrate, such as the illustrated bulk silicon substrate or, alternatively, the active layer of a semiconductor-on-insulator (SOI) substrate. The semiconductor material constituting the substrate 10 may be initially lightly doped to have a P-type conductivity. N-wells, of which N-Well 12 is representative, and P-wells, of which P-wells 14, 15 are representative, are formed across the substrate 10 by masking and implanting appropriate n-conductivity type impurities into the substrate 10 in respective unmasked regions. The semiconductor material of the N-well 12 is characterized by an n-type conductivity imparted by a suitable implanted N-type impurity, which may be selected from Group V dopants that include, but are not limited to, arsenic, phosphorus, and antimony. The semiconductor material of the P-wells 14, 15 is characterized by a P-type conductivity imparted by a suitable implanted P-type impurity, which may be selected from Group III dopants that include, but are not limited to, boron and indium. The topmost thickness of the substrate 10 may be constituted by an epitaxial device layer that is grown by an epitaxial process after the wells 12, 14, 15 are formed.

Shallow trench isolation regions, of which shallow trench isolation regions 16, 18, 20, 22, 24 are representative, and deep trench isolation regions, of which deep trench isolation regions 26, 28, 29, 30, 32 are representative, are formed in the semiconductor material of the substrate 10. Deep trench isolation regions 28, 30 are located between the N-well 12 and the P-wells 14, 15 and physically separate the N-well and P-wells 14, 15 from each other. Deep trench isolation regions 26 and 32 are located along the boundaries between one of the P-wells 14, 15 and other adjacent N-wells (not shown). Deep trench isolation region 29 is located between the deep trench isolation regions 28 and 30, and functions are described hereinbelow.

Each of the deep trench isolation regions 26, 28, 29, 30, 32 has respective sidewalls that extend from a top surface 34 of the substrate 10 into the substrate 10. The sidewalls of the deep trench isolation regions 26, 28, 29, 30, 32 have a substantially parallel alignment. The deep trench isolation regions 26, 28, 29, 30, 32 extend beyond a maximum depth 36 of the N-well 12 and a maximum depth 38 of the P-wells 14, 15 to electrically isolate the wells 12, 14, 15 from each other. The shallow trench isolation regions 16, 18, 20, 22, 24 extend into the substrate 10 to a shallower depth than the deep trench isolation regions 26, 28, 29, 30, 32. The shallow trench isolation regions 16, 18, 20, 22, 24 do not penetrate to the maximum depth 36 of the N-well 12 to maintain the electrical continuity of the N-well 12.

Shallow trenches, of which shallow trenches 40-44 are representative, are defined in the substrate 10 by a conventional lithography and etching process. Similarly, deep trenches, of which deep trenches 45-49 are representative, are defined in the substrate 10 by a conventional lithography and etching process. In each instance, the lithography process entails applying a hardmask on the top surface 34 of the substrate 10, applying a resist (not shown) on the hardmask, exposing the resist through a photomask to a pattern of radiation effective to create a latent pattern in the resist for a series of trenches, and developing the transferred pattern in the exposed resist. The hardmask is composed of a material, such as SiO₂, that etches selectively to the semiconductor material constituting the substrate 10. The trench pattern is transferred from the resist to the hardmask using an anisotropic dry etch, such as reactive-ion etching (RIE) or a plasma etching process. The etching process may be conducted in a single etching step or multiple etching steps with different etch chemistries, including a standard silicon RIE process for the substrate 10. The trenches are initially transferred to the hardmask as openings using the patterned resist as an etch mask. After the trenches are formed in the hardmask, residual resist is stripped by, for example, plasma ashing or use of a chemical stripper. Using the patterned hardmask as an etch mask, another anisotropic dry etch process is used to extend the sidewalls of trenches 40-44 or the sidewalls of trenches 45-49, as may be the case, into the substrate 10. The depth of the deep trenches 45-49 is greater than the maximum depth 36 of the N-well 12 and the P-wells 14, 15, which electrically isolates the N-well 12 from the P-wells 14, 15. On the other hand, the depth of the shallow trenches 40-44 is less than the maximum depth 36 of the N-well 12, which promotes electrical continuity of the N-well 12 beneath each of the shallow trenches 40-44. After etching is complete, each of the hardmasks is stripped to re-expose the top surface 34.

The shallow trench isolation regions 16, 18, 20, 22, 24 and deep trench isolation regions 26, 28, 29, 30, 32 are formed by depositing a dielectric material to fill the shallow trenches 40-44 and the deep trenches 45-49, respectively, and then planarizing the deposited dielectric material with a chemical-mechanical polishing (CMP) process or another suitable planarization technique. The dielectric material may comprise silicon oxide (SiO₂), and can be formed using standard techniques. For example, the dielectric material may be composed of an oxide like tetraethylorthosilicate (TEOS) deposited by thermal chemical vapor deposition (CVD) or a high density plasma (HDP) oxide. After planarization, the residual embedded dielectric material has a top surface 50 that is substantially coplanar with the top surface 34 of the substrate 10.

The deep trench isolation regions 26, 28, 29, 30, 32 parse the substrate 10 into device regions 52, 53a, 53b, 54, which are used to fabricate semiconductor devices, of which devices 56, 57, 58, 59 are representative. The devices 56-59 have the construction of low power metal-oxide-semiconductor field effect transistors (MOSFETs) and formed by a succession of conventional CMOS fabrication steps understood by a person of ordinary skill in the art. Device 56 includes a gate electrode 60 that is separated from the top surface 34 of the substrate 10 by a thin gate dielectric layer 64. Similarly, device 57 includes a gate stack in the form of a gate electrode 61 and a gate dielectric layer 65, device 58 includes a gate stack in the form of a gate electrode 62 and a gate dielectric layer 66, and device 59 includes a gate stack in the form of a gate electrode 63 and a gate dielectric layer 67. Additional gate stacks, including the representative gate stacks 68-73, are present.

Candidate dielectric materials for the gate dielectric layers 64-67 include, but are not limited to, silicon oxynitride (SiOₓN_{y}), silicon nitride (Si₃N₄), SiO₂, and layered stacks of these materials, as well as dielectric materials (e.g., hafnium-based high-k dielectrics) characterized by a relatively high permittivity. The gate electrodes 60-63 may be formed by conventional photolithography and etching process and may be composed of a conductor, such as a metal or doped polycrystalline silicon (i.e., doped polysilicon). Sidewall spacers (not shown) composed of a dielectric material, such as Si₃N₄, may be formed on the sidewalls of each of the gate electrodes 60-63 by a conventional spacer formation process.

Gate electrode 60 (and any sidewall spacers) functions as a self-aligned mask for one or more ion implantations that form a source region 76 and a drain region 77 for device 56. Gate electrode 61 (and any sidewall spacers) functions as a self-aligned mask for one or more ion implantations that form a source region 78 and a drain region 79 for device 57. Gate electrode 62 (and any sidewall spacers) functions as a self-aligned mask for one or more ion implantations that form a source region 80 and a drain region 81 for device 58. Gate electrode 63 (and any sidewall spacers) functions as a self-aligned mask for one or more ion implantations that form a source region 82 and a drain region 83 for device 59. Techniques for implanting an impurity to dope such source and drain regions are familiar to persons having ordinary skill in the art. A portion of substrate 10 situated between each set of source and drain regions comprises a channel in which current flows between each respective source and drain as a function of a control voltage applied to the respective one of the gate electrodes 60-63. Source/drain extensions and halo regions (not shown) may also be formed by angled implantation processes for each of the devices 56-59.

In one embodiment, each of the arrays of field effect transistors may comprise a memory cell, such as the representative memory cells 84, 86, 88, 90, of an SRAM 25, such as a six-transistor SRAM (6T-SRAM). Generally, each bit in one of the memory cells 84, 86, 88, 90 is stored on four field effect transistors, two of which are referred to as pull-up transistors and two of which are referred to as pull-down transistors, that form a flip-flop circuit containing two cross-coupled inverters. Two additional field effect transistors, referred to as pass-gate transistors, serve to control the access to the memory cell during read and write operations. In this embodiment, devices 56-59 in device region 53a are PFETs and each of the devices 56-59 constitutes one of the pull-down transistors of each of the memory cells 84, 86, 88, 90. Additional pull-down transistors, such as devices 91, 93, 95, 97, are provided in the N-well 12. Devices 91, 93, 95, 97 have a PFET construction similar to the PFET construction for devices 56-59. Hence, the source and drain regions 76-83 in the N-well 12 (device region 53a) and the source and drain regions (not shown) for devices 91, 93, 95, 97 in the N-well 12 (device region 53b) are doped with a P-type impurity species. Additional devices, including the representative devices 92, 94, 96, 98, having the construction of NFETs are formed in each of the P-wells 14, 15 and have source and drain regions (not shown) that are doped with an N-type impurity species. In the SRAM 25, the devices 92, 94, 96, 98 cooperate with device 56 to define memory cell 84. Two of these four NFETs function as pass-gate transistors and the other two NFETs function as pull-up transistors.

Device regions 52, 54 constitute strips of the P-wells 14, 15 parsed, respectively, by deep trench isolation regions 26, 28 and deep trench isolation regions 30, 32. In other words, device region 52 is bounded laterally by deep trench isolation regions 26, 28 and device region 54 is bounded laterally by deep trench isolation regions 30, 32. Consequently, deep trench isolation regions 26 and 28 bound the widths of the source and drain regions (not shown) of devices, like the representative devices 92, 94, in device region 52 and deep trench isolation regions 30 and 32 bound the widths of the source and drain regions (not shown) of devices, like the representative devices 96, 98, in device region 54.

Device regions 53a, 53b, constitute strips of the N-well 12 parsed by deep trench isolation regions 28, 29, 30. Deep trench isolation regions 28, 29 laterally bound device region 53a and deep trench isolation regions 29, 30 laterally bound device region 53b. As a result, deep trench isolation regions 28 and 29 bound the widths of the devices 56-59 in device region 53a and deep trench isolation regions 29 and 30 bound the widths of the devices 91, 93, 95, 97 in device region 53b. Shallow trench isolation regions 18 and 22 extend laterally between deep trench isolation regions 28 and 29. Consequently, shallow trench isolation regions 18, 22 isolate the source and drain regions 76-83, also referred to as diffusions, of the PFETs between the deep trench isolation regions 28 and 29. Shallow trench isolation regions 16, 20, 24 extend laterally between deep trench isolation regions 29 and 30. Consequently, shallow trench isolation regions 16, 20, 24 isolate the source and drain regions (not shown) of the PFETs between the deep trench isolation regions 29 and 30.

As apparent from FIGS. 1-3, the sidewalls of the deep trench isolation regions 45-49 are continuous in a direction, which is indicated on FIG. 1 by the double-headed arrow 85, that is aligned substantially perpendicular to a direction, which is indicated on FIG. 1 by the double-headed arrow 87, along which the sidewalls of the gate electrodes 60-63 and the gate stacks 68-73 are aligned. However, the N-well 12 is continuous between the deep trench isolation regions 28, 29 and between the deep trench isolation regions 29, 30. Furthermore, the N-well 12 is also continuous beneath each of the shallow trench isolation regions 16, 18, 20, 22, 24.

During the fabrication process, the memory cells 84, 86, 88, 90, the shallow trench isolation regions 16, 18, 20, 22, 24, and the deep trench isolation regions 26, 28, 29, 30, 32 are replicated by the CMOS processes across at least a portion of the surface area of the substrate 10. Standard processing follows, which includes formation of metallic contacts, metallization for the M1 level interconnect wiring, and interlayer dielectric layers, conductive vias, and metallization for upper level (M2-level, M3-level, etc.) interconnect wiring.

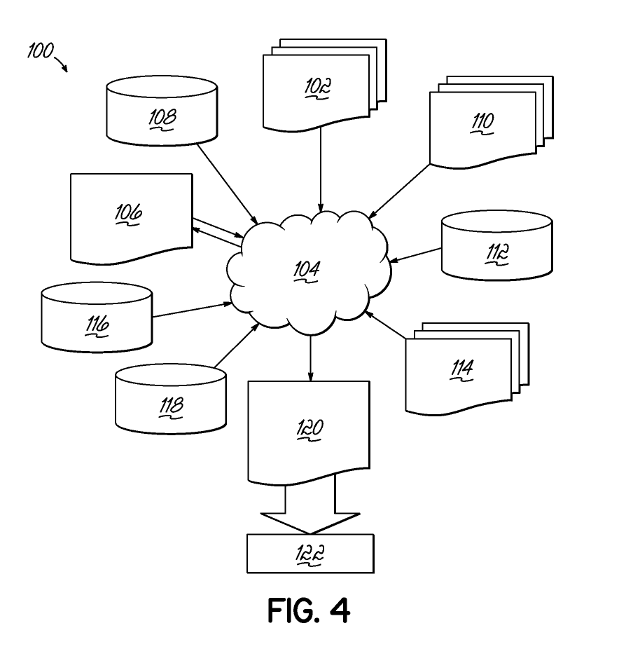

FIG. 4 shows a block diagram of an exemplary design flow 100 used for example, in semiconductor design, manufacturing, and/or test. Design flow 100 may vary depending on the type of IC being designed. For example, a design flow 100 for building an application specific IC (ASIC) may differ from a design flow 100 for designing a standard component or from a design flow 100 for instantiating the design into a programmable array, for example a programmable gate array (PGA) or a field programmable gate array (FPGA) offered by Altera® Inc. or Xilinx® Inc. Design structure 102 is preferably an input to a design process 104 and may come from an IP provider, a core developer, or other design company or may be generated by the operator of the design flow, or from other sources. Design structure 102 comprises an embodiment of the invention as shown in FIGS. 1, 2, 3 in the form of schematics or HDL, a hardware-description language (e.g., Verilog, VHDL, C, etc.). Design structure 102 may be contained on one or more machine readable medium. For example, design structure 102 may be a text file or a graphical representation of an embodiment of the invention as shown in FIGS. 1, 2, 3. Design process 104 preferably synthesizes (or translates) an embodiment of the invention as shown in FIGS. 1, 2, 3 into a netlist 106, where netlist 106 is, for example, a list of wires, transistors, logic gates, control circuits, I/O, models, etc. that describes the connections to other elements and circuits in an integrated circuit design and recorded on at least one of machine readable medium. For example, the medium may be a CD, a compact flash, other flash memory, a packet of data to be sent via the Internet, or other networking suitable means. The synthesis may be an iterative process in which netlist 106 is resynthesized one or more times depending on design specifications and parameters for the circuit.

Design process 104 may include using a variety of inputs; for example, inputs from library elements 108 which may house a set of commonly used elements, circuits, and devices, including models, layouts, and symbolic representations, for a given manufacturing technology (e.g., different technology nodes, 32 nm, 45 nm, 90 nm, etc.), design specifications 110, characterization data 112, verification data 114, design rules 116, and test data files 118 (which may include test patterns and other testing information). Design process 104 may further include, for example, standard circuit design processes such as timing analysis, verification, design rule checking, place and route operations, etc. One of ordinary skill in the art of integrated circuit design can appreciate the extent of possible electronic design automation tools and applications used in design process 104 without deviating from the scope and spirit of the invention. The design structure of the invention is not limited to any specific design flow.

Design process 104 preferably translates an embodiment of the invention as shown in FIGS. 1, 2, 3, along with any additional integrated circuit design or data (if applicable), into a second design structure 120. Design structure 120 resides on a storage medium in a data format used for the exchange of layout data of integrated circuits and/or symbolic data format (e.g. information stored in a GDSII (GDS2), GL1, OASIS, map files, or any other suitable format for storing such design structures). Design structure 120 may comprise information such as, for example, symbolic data, map files, test data files, design content files, manufacturing data, layout parameters, wires, levels of metal, vias, shapes, data for routing through the manufacturing line, and any other data required by a semiconductor manufacturer to produce an embodiment of the invention as shown in FIGS. 1, 2, 3. Design structure 120 may then proceed to a stage 122 where, for example, design structure 120 proceeds to tape-out, is released to manufacturing, is released to a mask house, is sent to another design house, is sent back to the customer, etc.

References herein to terms such as “vertical”, “horizontal”, etc. are made by way of example, and not by way of limitation, to establish a frame of reference. The term “horizontal” as used herein is defined as a plane parallel to a conventional plane of a semiconductor substrate, regardless of its actual three-dimensional spatial orientation. The term “vertical” refers to a direction perpendicular to the horizontal, as just defined. Terms, such as “on”, “above”, “below”, “side” (as in “sidewall”), “upper”, “lower”, “over”, “beneath”, and “under”, are defined with respect to the horizontal plane. It is understood that various other frames of reference may be employed for describing the invention without departing from the spirit and scope of the invention. It is also understood that features of the invention are not necessarily shown to scale in the drawings. Furthermore, to the extent that the terms “includes”, “having”, “has”, “with”, or variants thereof are used in either the detailed description or the claims, such terms are intended to be inclusive in a manner similar to the term “comprising.”

It will be understood that when an element as a layer, region or substrate is described as being “on” or “over” another element, it can be directly on or over the other element or intervening elements may also be present. In contrast, when an element is described as being “directly on” or “directly over” another element, there are no intervening elements present. It will also be understood that when an element is described as being “connected” or “coupled” to another element, it can be directly connected or coupled to the other element or intervening elements may be present. In contrast, when an element is described as being “directly connected” or “directly coupled” to another element, there are no intervening elements present.

The fabrication of the semiconductor structure herein has been described by a specific order of fabrication stages and steps. However, it is understood that the order may differ from that described. For example, the order of two or more fabrication steps may be swapped relative to the order shown. Moreover, two or more fabrication steps may be conducted either concurrently or with partial concurrence. In addition, various fabrication steps may be omitted and other fabrication steps may be added. It is understood that all such variations are within the scope of the present invention. It is also understood that features of the present invention are not necessarily shown to scale in the drawings.

While the invention has been illustrated by a description of various embodiments and while these embodiments have been described in considerable detail, it is not the intention of the applicants to restrict or in any way limit the scope of the appended claims to such detail. Additional advantages and modifications will readily appear to those skilled in the art. Thus, the invention in its broader aspects is therefore not limited to the specific details, representative apparatus and method, and illustrative example shown and described. Accordingly, departures may be made from such details without departing from the spirit or scope of applicants' general inventive concept.

What is claimed is:

1. A method of manufacturing a device structure using a semiconductor layer having a top surface, the method comprising:
forming a first well of a first conductivity type in the semiconductor layer;
forming first and second deep trench isolation regions in the semiconductor layer that laterally bound a first device region in the first well;
forming a first plurality of doped regions of a second conductivity type and a second plurality of doped regions of the second conductivity type in the first device region;
forming a shallow trench isolation region that extends laterally across the first device region from the first deep trench isolation region to the second deep trench isolation region, the shallow trench isolation region disposed in the first device region between the first plurality of doped regions and the second plurality of doped regions and the shallow trench isolation region extending from the top surface into the semiconductor layer to a first depth such that the first well is continuous beneath the shallow trench isolation region; and
forming a first gate stack on the top surface of the semiconductor layer, the first gate stack configured to control carrier flow between one of the first plurality of doped regions and another of the first plurality of doped regions.

2. The method of claim 1 wherein each of each of the first and second deep trench isolation regions has a sidewall, and the sidewall of the first deep trench isolation region has a substantially parallel alignment with the sidewall of the second deep trench isolation region.

3. The method of claim 2 wherein the first gate stack includes a sidewall that is aligned substantially perpendicular to the sidewall of the first deep trench isolation region and the sidewall of the second deep trench isolation region.

4. The method of claim 1 wherein each of the first plurality of doped regions and each of the second plurality of doped regions has a width bounded in the first device region between the first and second deep trench isolation regions.

5. The method of claim 1 further comprising:
forming a second device region in the first well that is separated from the first device region by the second deep trench isolation region, the first and second device regions electrically isolated from each other by the second deep trench isolation region.

6. The method of claim 5 further comprising:
forming a third plurality of doped regions of the second conductivity type in the second device region.

7. The method of claim 1 further comprising:
forming a second well of the second conductivity type in the semiconductor layer, one of the first and second deep trench isolation regions extending to a second depth in the semiconductor layer that is effective to electrically isolate the second well from the first well.

8. The method of claim 7 wherein the first conductivity type is P-type, the second conductivity type is N-type, the first well is composed of N-type semiconductor material, and the first plurality and second pluralities of doped regions are composed of P-type semiconductor material.

9. The method of claim 1 further comprising:
forming a second gate stack on the top surface of the semiconductor layer, the second gate stack configured to control carrier flow between one of the second plurality of doped regions and another of the second plurality of doped regions.

10. The method of claim 1 wherein the first plurality of doped regions and the first gate stack are components of a field effect transistor of a static random access memory cell.
